(19) United States
(12) Patent Application Publication
(10) Pub. No.: US 2025/0183050 A1
(43) Pub. Date: Jun. 5, 2025

(54) METHOD FOR TREATING OBJECT TO BE TREATED, TREATMENT LIQUID, AND METHOD FOR MANUFACTURING ELECTRONIC DEVICE

(71) Applicant: FUJIFILM CORPORATION, Tokyo (JP)

(72) Inventors: Atsushi Mizutani, Shizuoka (JP); Moe Narita, Shizuoka (JP); Shota Oi, Shizuoka (JP)

(21) Appl. No.: 19/051,693

(22) Filed: Feb. 12, 2025

Related U.S. Application Data
(63) Continuation of application No. PCT/JP2023/030247, filed on Aug. 23, 2023.

(30) Foreign Application Priority Data
Aug. 31, 2022 (JP) 2022-138113
Nov. 30, 2022 (JP) 2022-191606

(51) Int. Cl. H01L 21/311; C23C 22/54; C23C 22/64; C23C 22/82; H01L 21/02

(52) U.S. Cl. CPC H01L 21/31111; C23C 22/54; C23C 22/64; C23C 22/82; H01L 21/02175; H01L 21/02244

(57) ABSTRACT

An object of the present invention is to provide a method for treating an object to be treated, which has an excellent etching amount with respect to a metal layer containing at least one selected from the group consisting of molybdenum and tungsten and has excellent flatness of a surface of the metal layer after the treatment. The method for treating an object to be treated according to an embodiment of the present invention includes a step 1 of bringing the object to be treated, which has a metal layer containing at least one selected from the group consisting of molybdenum and tungsten, into contact with a first treatment liquid to form a metal oxide layer, and a step 2 of bringing the object to be treated, which has the metal oxide layer, into contact with a second treatment liquid to remove the metal oxide layer, in which the first treatment liquid contains an organic solvent and an oxidizing agent, and the second treatment liquid contains water.

### CROSS-REFERENCE TO RELATED APPLICATIONS

This application is a Continuation of PCT International Application No. PCT/JP2023/030247 filed on Aug. 23, 2023, which claims priority under 35 U.S.C. § 119(a) to Japanese Patent Application No. 2022-138113 filed on Aug. 31, 2022 and Japanese Patent Application No. 2022-191606 filed on Nov. 30, 2022. The above applications are hereby expressly incorporated by reference, in their entirety, into the present application.

### BACKGROUND OF THE INVENTION

### 1. Field of the Invention

The present invention relates to a method for treating an object to be treated, a treatment liquid, and a method for manufacturing an electronic device.

### 2. Description of the Related Art

As miniaturization of electronic devices progresses, there is an increasing demand for efficiently and accurately performing an etching treatment for removing unnecessary metal-containing substances on a substrate in a manufacturing process of an electronic device.

As the above-described method, JP2022-509816A discloses a method for forming a metal interconnect layer, the method including a step of forming a molybdenum layer on a substrate, a step of forming a masking layer on the molybdenum layer, a step of patterning the masking layer to expose a part of the molybdenum layer, a step of modifying the exposed portion of the molybdenum layer with oxygen to form an oxidized molybdenum portion of the molybdenum layer, and a step of removing the oxidized molybdenum portion from the substrate.

### SUMMARY OF THE INVENTION

The present inventors have studied the method described in JP2022-509816A, and have found that there is room for improvement in flatness of a surface of a metal layer exposed after performing the step of removing the molybdenum oxide.

It is desirable that the surface of the metal layer after the etching treatment has high flatness.

In addition, from the viewpoint of manufacturing efficiency, an etching treatment method is generally required to have an excellent etching amount.

Therefore, an object of the present invention is to provide a method for treating an object to be treated, in which, in a case of being applied to an object to be treated having a metal layer containing at least one selected from the group consisting of molybdenum and tungsten, an etching amount is excellent and flatness of a surface of the metal layer after the treatment is also excellent. In addition, another object of the present invention is to provide a treatment liquid used for treating an object to be treated and a method for manufacturing an electronic device, which includes the above-described treatment method.

As a result of conducting an extensive investigation to achieve the objects, the present inventors have found that the above-described objects can be achieved by the following constitution.

[1] A method for treating an object to be treated, comprising:
a step 1 of bringing the object to be treated, which has a metal layer containing at least one selected from the group consisting of molybdenum and tungsten, into contact with a first treatment liquid to form a metal oxide layer; and
a step 2 of bringing the object to be treated, which has the metal oxide layer, into contact with a second treatment liquid to remove the metal oxide layer,
in which the first treatment liquid contains an organic solvent and an oxidizing agent, and
the second treatment liquid contains water.

[2] The method for treating an object to be treated according to claim [1],
in which a content of the organic solvent is 80% by mass or more with respect to a total mass of the first treatment liquid.

[3] The method for treating an object to be treated according to [1] or [2],
in which a relative permittivity of the organic solvent is 50 or less.

[4] The method for treating an object to be treated according to any one of [1] to [3],
in which a relative permittivity of the organic solvent is 3 to 20.

[5] The method for treating an object to be treated according to any one of [1] to [4],
in which the organic solvent includes at least one selected from the group consisting of an ester solvent, an ether solvent, and an amine solvent.

[6] The method for treating an object to be treated according to any one of [1] to [5],
in which the organic solvent includes at least one selected from the group consisting of ethyl acetate, butyl acetate, ethyl lactate, tetraethylene glycol dimethyl ether, diethylene glycol dibutyl ether, diethylene glycol dimethyl ether, dipropylene glycol dimethyl ether, propylene glycol monomethyl ether, propylene glycol monomethyl ether acetate, diethylene glycol diethyl ether, tetrahydrofuran, and pyridine.

[7] The method for treating an object to be treated according to any one of [1] to [6],
in which the first treatment liquid contains water, and a content of the water is 0.001% to 20.0% by mass with respect to a total mass of the first treatment liquid.

[8] The method for treating an object to be treated according to [7],
in which the content of the water is 0.1% to 10.0% by mass with respect to the total mass of the first treatment liquid.

[9] The method for treating an object to be treated according to any one of [1] to [8],
in which the oxidizing agent includes at least one selected from the group consisting of a quinone compound and a hydroquinone.

[10] The method for treating an object to be treated according to any one of [1] to [9],
in which the oxidizing agent includes at least one selected from the group consisting of 1,2-benzoquinone, 1,4-benzoquinone, hydroquinone, 1,4-naphthoquinone, ubiquinone, and anthraquinone.

[11] The method for treating an object to be treated according to any one of [1] to [10],
in which the step 1 and the step 2 are repeatedly performed.

[12] A treatment liquid applied to an object to be treated, which has a metal layer containing at least one selected from the group consisting of molybdenum and tungsten, the treatment liquid comprising:
an organic solvent; and
an oxidizing agent,
in which a content of the organic solvent is 80% by mass or more with respect to a total mass of the treatment liquid.

[13] A method for manufacturing an electronic device, comprising:
the method for treating an object to be treated according to any one of [1] to [11].

According to the present invention, it is possible to provide a method for treating an object to be treated, in which, in a case of being applied to an object to be treated having a metal layer containing at least one selected from the group consisting of molybdenum and tungsten, an etching amount of the metal layer is excellent and flatness of a surface of the metal layer after the treatment is also excellent. In addition, according to the present invention, it is also possible to provide a treatment liquid used for treating an object to be treated, and a method for manufacturing an electronic device.

### DESCRIPTION OF THE PREFERRED EMBODIMENTS

Hereinafter, the present invention will be specifically described.

The description of the configuration requirements described below is made on the basis of representative embodiments of the present invention, but it should not be construed that the present invention is limited to those embodiments.

Hereinafter, the meaning of each description in the present specification will be expressed.

In the present specification, numerical ranges represented by “to” include numerical values before and after “to” as lower limit values and upper limit values.

In addition, in the present specification, in a case where there are two or more components corresponding to a certain component, “content” of such a component means the total content of the two or more components.

In the present specification, “ppm” means “parts-per-million (10⁻⁶)”, and “ppb” means “parts-per-billion (10⁻⁹)”.

In the present specification, the “room temperature” is 25° C. unless otherwise specified.

The method for treating an object to be treated (hereinafter, also referred to as “the present treatment method”.) according to an embodiment of the present invention includes a step 1 of bringing the object to be treated, which has a metal layer containing at least one selected from the group consisting of molybdenum and tungsten, into contact with a first treatment liquid to form a metal oxide layer, and a step 2 of bringing the object to be treated, which has the metal oxide layer, into contact with a second treatment liquid to remove the metal oxide layer, in which the first treatment liquid contains an organic solvent and an oxidizing agent, and the second treatment liquid contains water.

A reason why the method for treating an object to be treated according to the embodiment of the present invention can solve the problems of the present invention by having the above-described configuration is not always clear, but the present inventors speculate as follows.

The mechanism by which the effect is obtained is not limited by the following supposition. In other words, even in a case where an effect is obtained by a mechanism other than the following, it is included in the scope of the present invention.

The oxidizing agent contained in the first treatment liquid oxidizes the metal contained in the metal layer of the object to be treated, and forms a metal oxide layer on the surface of the metal layer. In this case, since the organic solvent contained in the first treatment liquid has a low dissolving ability for the metal oxide layer, removal of the metal oxide layer in the step 1 is suppressed. That is, in order to sequentially proceed the formation and removal of the metal oxide layer by the step 1 and the step 2, unintended excessive etching and/or variation in an etching amount in a plane in the step 1 are suppressed. As a result, it is presumed that flatness of the exposed surface of the metal layer is excellent after performing the step 2 of removing the metal oxide layer on a surface of the object to be treated with the second treatment liquid containing water having a high dissolving ability for the metal oxide layer.

Hereinafter, the flatness of the surface of the metal layer after performing the treatment method according to the embodiment of the present invention is also simply referred to as “flatness”. In addition, the fact that at least one of the etching amount or the flatness is more excellent is also referred to as “effect of the present invention is more excellent”.

Hereinafter, each step will be described.

### Step 1

The present treatment method includes the step 1 of bringing an object to be treated, which has a metal layer containing at least one selected from the group consisting of molybdenum and tungsten, into contact with a first treatment liquid to form a metal oxide layer.

Hereinafter, a material (an object to be treated and a first treatment liquid) used in the step 1 and the procedure thereof will be described.

### Object to be Treated

The object to be treated according to the embodiment of the present invention is not particularly limited as long as it has a metal layer containing at least one (hereinafter, also referred to as a “specific metal”.) selected from the group consisting of molybdenum and tungsten. Examples of the object to be treated include a substrate having the above-described metal layer.

In a case where the substrate has a metal layer, a location where the metal layer is present may be, for example, any of a front and back surface, a side surface, a groove, or the like of the substrate. In addition, in a case where the substrate contains a metal layer, the metal includes not only a case in which the metal layer is directly present on the surface of the substrate, but also a case in which the metal layer is present on the substrate through another layer.

The metal layer may be disposed only on one side of a main surface of the substrate, or may be disposed on both sides of the main surface of the substrate. The metal layer may be disposed on the entire main surface of the substrate or may be disposed on a part of the main surface of the substrate.

The metal layer is a layer formed of a metal, and contains a specific metal as described above. More specifically, the metal constituting the metal layer contains a simple substance of the specific metal or an alloy of the specific metal and another metal.

Examples of the other metals include copper (Cu), cobalt (Co), ruthenium (Ru), aluminum (Al), titanium (Ti), tantalum (Ta), rhodium (Rh), chromium (Cr), hafnium (Hf), osmium (Os), platinum (Pt), nickel (Ni), manganese (Mn), zirconium (Zr), lanthanum (La), and iridium (Ir).

The metal layer may be an alloy consisting of molybdenum and tungsten.

The metal layer preferably contains a specific metal as a main component. The expression “contains a specific metal as a main component” means that a content of specific metal atoms is the highest among metal atoms contained in the metal layer. Examples of the metal layer containing a specific metal as a main component include a simple substance of molybdenum, a simple substance of tungsten, a molybdenum alloy (an alloy in which a metal atom having a highest content is molybdenum), and a tungsten alloy (an alloy in which a metal atom having a highest content is tungsten), and a simple substance of molybdenum or a molybdenum alloy is preferable and a simple substance of molybdenum is more preferable.

The content of the specific metal contained as the main component in the metal layer is preferably 50% to 100% by mass, more preferably 80% to 100% by mass, and still more preferably 95% to 100% by mass with respect to a total mass of the metal layer.

A form of the metal layer in the object to be treated is not particularly limited, and examples thereof include a form in which the metal layer is disposed in a film shape (metal-containing film) and a form in which the metal layer is disposed in a wiring shape (metal-containing wiring).

In a case where the metal layer has a film shape or a wiring shape, the thickness thereof is not particularly limited, and may be appropriately selected according to use application. The thickness of the metal layer having a film shape or a wiring shape is preferably 500 nm or less, more preferably 200 nm or less, and still more preferably 50 nm or less. The lower limit thereof is not particularly limited, but is preferably 1 nm or more.

The type of substrate in the object to be treated is not particularly limited. Examples of the substrate include various substrates such as a semiconductor wafer, a glass substrate for a photomask, a glass substrate for liquid crystal display, a glass substrate for plasma display, a substrate for field emission display (FED), a substrate for an optical disk, a substrate for a magnetic disk, and a substrate for a magneto-optical disk.

Examples of materials constituting the semiconductor substrate include silicon, silicon germanium, a Group III-V compound such as GaAs, and any combination of these.

The size, thickness, shape, and layer structure of the substrate are not particularly limited, and can be appropriately selected as desired.

In a case where the object to be treated is a semiconductor substrate, the semiconductor substrate may have an insulating film.

The insulating film in the object to be treated is not particularly limited. Examples thereof include an insulating film including one or more materials selected from a group consisting of silicon nitride (SiN), silicon oxide, silicon carbide (SiC), silicon carbonitride, silicon oxycarbide (SiOC), silicon oxynitride, and tetraethoxysilane (TEOS). Among these, SiN, TEOS, SiC, or SiOC is preferable as the above-described material. In addition, the insulating film may be formed of a plurality of films.

The object to be treated may have various layers and/or structures as desired, in addition to the above. For example, in a case where the object to be treated is a substrate, the object to be treated may have members such as a barrier layer, a metal wire, a gate electrode, a source electrode, a drain electrode, an insulating layer, a ferromagnetic layer, an integrated circuit structure, and/or a non-magnetic layer.

The method for manufacturing an object to be treated is not particularly limited.

The method for forming the above-described insulating film and metal layer on a substrate is not particularly limited as long as it is a method generally performed in this field.

Examples of the method for forming the insulating film include a method in which the wafer constituting the semiconductor substrate is subjected to a heat treatment in the presence of oxygen gas to form a silicon oxide film, and then a gas of silane and ammonia is introduced thereto to form a silicon nitride film by a chemical vapor deposition (CVD) method.

Examples of the method for forming a metal layer on the insulating film include a sputtering method, a physical vapor deposition (PVD) method, an atomic layer deposition (ALD) method, a chemical vapor deposition method, and a molecular beam epitaxy (MBE) method.

In addition, the above-described method may be performed through a predetermined mask to form a patterned metal layer on a substrate.

### First Treatment Liquid

The first treatment liquid contains an organic solvent and an oxidizing agent.

In a case where the first treatment liquid is brought into contact with the object to be treated having a metal layer containing at least one selected from the group consisting of molybdenum and tungsten, the first treatment liquid oxidizes the metal layer to form a metal oxide layer.

Hereinafter, each component of the first treatment liquid and the manufacturing method thereof will be described.

### <Organic Solvent>

The first treatment liquid contains an organic solvent.

The organic solvent is not particularly limited as long as it is an organic compound that is a liquid at room temperature and 1 atm.

Examples of the organic solvent include an ester solvent, an ether solvent, an alcohol solvent, an amine solvent, a hydrocarbon solvent, a sulfoxide solvent, a carboxylic acid solvent, a sulfone solvent, a ketone solvent, a nitrile solvent, and an amide solvent.

From the viewpoint of more excellent flatness, relative permittivity of the organic solvent is preferably 50 or less, more preferably 20 or less, and still more preferably 15 or less. In addition, the relative permittivity of the organic solvent is preferably 3 or more from the viewpoint that an effect of the present invention is more excellent.

The above-described relative permittivity is a value at 15° C. to 30° C. unless otherwise specified. It is preferable that the above-described relative permittivity has a value at 20° C. within the above-described range.

As the relative permittivity, values described in “Solvent Handbook (4th edition)” (Kodansha, 1982) can be used. In a case where there is no description in the above-described document, a value measured by a known method can be used. A known method for measuring relative permittivity is not particularly limited, and for example, a method based on JIS C2138 and a method described in paragraph of [0022] JP2020-021581A can be used.

In a case where two or more organic solvents are used in combination, it is preferable that relative permittivity of each organic solvent satisfies the above-described requirement.

In addition, from the viewpoint of an excellent etching amount, the organic solvent is preferably miscible with water.

The organic solvent may include an isomeric compound.

The ester solvent is an organic solvent having an ester bond (—C(═O)—O—).

Examples of the ester solvent include an alkyl acetate ester such as ethyl acetate and butyl acetate, an alkyl lactate ester such as ethyl lactate, an alkoxypropanoic acid alkyl ester such as methyl 3-methoxypropanoate, a glycol ester, and cyclic esters such as propylene carbonate, ethylene carbonate, and diethyl carbonate.

The glycol ester is a compound in which a hydroxy group at one terminal or both terminals of glycol forms an ester bond, and examples thereof include glycol monoesters such as propylene glycol monomethyl ether acetate, ethylene glycol monoacetate, diethylene glycol monoacetate, ethylene glycol monomethyl ether acetate, propylene glycol monoethyl ether acetate (PGMEA), and ethylene glycol monoethyl ether acetate, and glycol diesters such as ethylene glycol diacetate and propylene glycol diacetate (PGDA).

As the ester solvent, an alkyl acetate ester, an alkyl lactate ester, or a glycol ester is preferable.

The ether solvent is an organic solvent having an ether bond (—O—), and does not include the above-described ester solvent and glycol.

Examples of the ether solvent include dialkyl ethers such as diethyl ether, diisopropyl ether, dibutyl ether, t-butyl methyl ether, and cyclohexyl methyl ether, glycol ethers, and cyclic ethers such as tetrahydrofuran and 1,4-dioxane.

The glycol ether is a compound in which a hydroxy group at one terminal or both terminals of a glycol is substituted with an alkoxy group, and examples thereof include alkylene glycol dialkyl ethers such as diethylene glycol dimethyl ether, diethylene glycol diethyl ether, diethylene glycol dibutyl ether, tetraethylene glycol dimethyl ether, dipropylene glycol dimethyl ether, triethylene glycol diethyl ether, tetraethylene glycol diethyl ether, ethylene glycol dimethyl ether, and triethylene glycol dimethyl ether, and alkylene glycol alkyl ethers such as propylene glycol monomethyl ether, ethylene glycol monomethyl ether, ethylene glycol monoethyl ether, ethylene glycol monopropyl ether, ethylene glycol monoisopropyl ether, ethylene glycol monobutyl ether, diethylene glycol monomethyl ether, diethylene glycol monopropyl ether, diethylene glycol monobutyl ether, diethylene glycol monoethyl ether, triethylene glycol monomethyl ether, triethylene glycol monoethyl ether, and triethylene glycol monobutyl ether.

As the ether solvent, a glycol ether or a cyclic ether is preferable, a glycol ether or tetrahydrofuran is more preferable, and a glycol ether is still more preferable.

The alcohol solvent is an organic solvent having a hydroxy group, and does not include the above-described ester solvent and the above-described ether solvent.

Examples of the alcohol solvent include monoalcohols such as propanol, isopropyl alcohol (IPA), t-butyl alcohol, methanol, ethanol, 1-butanol, 2-butanol, isobutyl alcohol, 2-pentanol, t-pentyl alcohol, hexanol, 3-methoxy-3-methyl-1-butanol (MMB), 3-methoxy-1-butanol, 1-methoxy-2-butanol, allyl alcohol, propargyl alcohol, 2-butenyl alcohol, 3-butenyl alcohol, 4-penten-2-ol, tetrahydrofurfuryl alcohol, furfuryl alcohol, and benzyl alcohol, and glycols such as ethylene glycol, propylene glycol, diethylene glycol, dipropylene glycol, triethylene glycol, tetraethylene glycol, 2-methyl-1,3-propanediol, 1,3-propanediol, 2,2-dimethyl-1,3-propanediol, 1,4-butanediol, 1,3-butanediol, 1,2-butanediol, 2,3-butanediol, hexylene glycol, pinacol, and 1,3-cyclopentanediol, where monoalcohol is preferable.

The amine solvent is an organic solvent having an amino group and not having an amide bond, and does not include the above-described ester solvent, ether solvent, and alcohol solvent.

Examples of the amine solvent include pyridine, triethylamine, and diethylamine.

Examples of the hydrocarbon solvent include aliphatic hydrocarbon solvents such as hexane, heptane, pentane, octane, cyclohexane, methylcyclohexane, cyclopentane, and methylcyclopentane, and aromatic hydrocarbon solvents such as toluene, xylene, and ethylbenzene.

Examples of other solvents other than the above-described solvents include sulfoxide solvents such as dimethyl sulfoxide, carboxylic acid solvents such as formic acid, acetic acid, and propionic acid, amide solvents such as N-methyl-2-pyrrolidone, N,N-dimethylformamide, 1-methyl-2-pyrrolidone, 2-pyrrolidinone, 1,3-dimethyl-2-imidazolidinone, ε-caprolactam, formamide, N-methylformamide, acetamide, N-methylacetamide, N,N-dimethylacetamide, N-methylpropanamide, and hexamethylphosphoric triamide, sulfone solvents such as sulfolane, 3-methylsulfolane, and 2,4-dimethylsulfolane, ketone solvents such as acetone, dimethyl ketone (propanone), cyclobutanone, cyclopentanone, cyclohexanone, methyl ethyl ketone (2-butanone), 5-hexanedione, methyl isobutyl ketone, 1,4-cyclohexanedione, 1,3-cyclohexanedione, and cyclohexanone, and nitrile solvents such as acetonitrile.

As the organic solvent, an ester solvent, an ether solvent, or an amine solvent is preferable, and an ester solvent or a glycol ether is more preferable.

Among these, as the organic solvent, ethyl acetate, butyl acetate, ethyl lactate, propylene glycol monomethyl ether acetate, propylene glycol monomethyl ether, dipropylene glycol dimethyl ether, diethylene glycol dimethyl ether, diethylene glycol dibutyl ether, tetraethylene glycol dimethyl ether, diethylene glycol diethyl ether, tetrahydrofuran, pyridine, isopropyl alcohol, or t-butyl alcohol is preferable, ethyl acetate, butyl acetate, ethyl lactate, propylene glycol monomethyl ether acetate, propylene glycol monomethyl ether, dipropylene glycol dimethyl ether, diethylene glycol dimethyl ether, diethylene glycol dibutyl ether, tetraethylene glycol dimethyl ether, diethylene glycol diethyl ether, tetrahydrofuran, or pyridine is more preferable, and ethyl acetate, butyl acetate, ethyl lactate, propylene glycol monomethyl ether acetate, propylene glycol monomethyl ether, dipropylene glycol dimethyl ether, diethylene glycol dimethyl ether, diethylene glycol dibutyl ether, tetraethylene glycol dimethyl ether, or diethylene glycol diethyl ether is still more preferable.

The organic solvent may be used alone, or two or more types thereof may be used in combination.

From the viewpoint that the effect of the present invention is more excellent, the content of the organic solvent is preferably 80% by mass or more, more preferably 85% by mass or more, and still more preferably 90% by mass or more with respect to a total mass of the first treatment liquid. The upper limit thereof is lower than 100% by mass, preferably 99.9% by mass or less and more preferably 99.0% by mass or less.

### <Oxidizing Agent>

The first treatment liquid contains an oxidizing agent.

The oxidizing agent is not particularly limited as long as it is a compound having a function of oxidizing a specific metal, and examples thereof include a quinone compound, hydroquinone, and hydrogen peroxide, where a quinone compound or hydroquinone is preferable.

A molecular weight of the oxidizing agent is preferably 30 to 1500, more preferably 80 to 1500, and still more preferably 100 to 1500.

The quinone compound is a compound having a quinone skeleton.

A ring structure of the quinone compound may be either a monocyclic ring or a fused ring.

Examples of the quinone compound include 1,4-benzoquinone, 1,2-benzoquinone, 1,4-naphthoquinone, ubiquinone, anthraquinone, toluquinone, dimethyl-1,4-benzoquinone, chloranil, and aloxane.

Examples of the other oxidizing agents include hydroquinone, a persulfide such as monopersulfate or disulfate, an oxidohalide such as chloric acid, perchloric acid, chlorous acid, hypochlorous acid, an iodide, a periodate, iodic acid, and periodic acid, a peroxy acid such as perboric acid, peracetic acid, and perbenzoic acid, nitric acid, nitrous acid, sulfuric acid, and salts thereof.

In addition, examples of the oxidizing agent also include hydrogen peroxide, a percarbonate, a permanganate, an ammonium peroxodisulfate, a cerium compound such as ammonium cerium nitrate, and a ferricyanide such as potassium ferricyanide.

Among these, as the oxidizing agent, 1,4-benzoquinone, hydroquinone, 1,2-benzoquinone, 1,4-naphthoquinone, ubiquinone, or anthraquinone is preferable, and 1,4-benzoquinone, hydroquinone, 1,2-benzoquinone, or 1,4-naphthoquinone is more preferable.

The oxidizing agent may be used alone or may be used in a combination of two types or more.

A content of the oxidizing agent is preferably 0.01% to 20.0% by mass, more preferably 0.1% to 10.0% by mass, and still more preferably 0.5% to 7.5% by mass with respect to the total mass of the first treatment liquid.

### <Water>

The first treatment liquid may contain water.

The water contained in the first treatment liquid may be any water as long as it does not adversely affect the object to be treated.

Among these, water that has been subjected to a purification treatment, such as distilled water, deionized water (DIW), and pure water (ultrapure water), is preferable, and pure water (ultrapure water) or DIW is more preferable from the viewpoint of having a smaller effect on the semiconductor substrate.

From the viewpoint of an excellent etching amount, a content of water is preferably 0.0001% by mass or more, more preferably 0.001% by mass or more, and still more preferably 0.1% by mass or more with respect to the total mass of the first treatment liquid, and from the viewpoint of excellent flatness, the content of water is preferably 20.0% by mass or less, more preferably 15.0% by mass or less, and still more preferably 10.0% by mass or less with respect to a total mass of the first treatment liquid.

### <Other Components>

The first treatment liquid may contain other components in addition to the above. Examples of the other components include an acidic compound and a basic compound. In addition, examples of the other components also include raw materials used for synthesizing the organic solvent, by-products generated during the synthesis of the organic solvent, metal components, and coarse particles.

### (Acidic Compound)

The acidic compound is a compound that is acidic (has a pH of less than 7.0) in an aqueous solution, and does not contain the above-described oxidizing agent.

Examples of the acidic compound include an inorganic acid and an organic acid.

Examples of the inorganic acid include hydrochloric acid, nitric acid, sulfuric acid, phosphoric acid, hydrobromic acid, and hydrofluoric acid.

Examples of the organic acid include carboxylic acids such as phthalic acid, succinic acid, maleic acid, malonic acid, oxalic acid, tartaric acid, malic acid, citric acid, benzoic acid, and lactic acid, and sulfonic acids such as paratoluenesulfonic acid, benzenesulfonic acid, and methanesulfonic acid.

The acidic compound may be used alone or in combination of two or more thereof.

A content of the acidic compound is preferably 0.01% to 10% by mass, and more preferably 0.1% to 5% by mass with respect to the total mass of the treatment liquid.

### (Basic Compound)

The basic compound is a compound which exhibits basicity (a pH of more than 7.0) in an aqueous solution.

Examples of the basic compound include a basic inorganic compound and a basic organic compound.

Examples of the basic inorganic compound include alkali metal hydroxides such as lithium hydroxide, sodium hydroxide, potassium hydroxide, and cesium hydroxide, alkaline earth metal hydroxides such as calcium hydroxide, strontium hydroxide, and barium hydroxide, and ammonia.

Examples of the basic organic compound include an amine oxide, nitro, nitroso, oxime, ketoxime, aldoxime, lactam, isocyanides, urea, an amine compound, and a quaternary ammonium salt.

The basic compound may be used alone or in combination of two or more thereof.

A content of the basic compound is preferably 0.001% to 10% by mass, and more preferably 0.01% to 5% by mass with respect to the total mass of the treatment liquid.

### (Metal Component)

The first treatment liquid may contain a metal component.

Examples of the metal component include metal particles and metal ions. For example, in a case of being referred to as the content of the metal component, it indicates the total content of metal particles and metal ions. The composition may contain either metal particles or metal ions, or it may contain both metal particles and metal ions.

Examples of the metal atom contained in the metal component include metal atoms selected from the group consisting of Ag, Al, As, Au, Ba, Ca, Cd, Co, Cr, Cu, Fe, Ga, Ge, K, Li, Mg, Mn, Mo, Na, Ni, Pb, Sn, Sr, Ti, Zn, and Zr.

The metal component may contain only one metal atom or two or more metal atoms.

The metal component may be any of a metal component that is intentionally added, a metal component that is inevitably contained in each component of the first treatment liquid, or a metal component that is inevitably contained during production, storage, and/or transfer of the first treatment liquid.

The metal particles may be present in any form of a simple substance, an alloy, or a form in which a metal is associated with an organic substance.

In a case where the first treatment liquid contains a metal component, the content of the metal component is 0.01 ppt by mass to 10 ppm by mass with respect to the total mass of the first treatment liquid in a large number of cases, and it is preferably 0.1 ppt by mass to 1 ppm by mass and more preferably 0.1 ppt by mass to 100 ppb by mass.

The type and content of the metal component in the first treatment liquid can be measured by inductively coupled plasma mass spectrometry (ICP-MS).

In the ICP-MS method, the content of the metal component to be measured is measured regardless of the existence form thereof. As a result, the total mass of metal particles to be measured and metal ions are quantified as the content of the metal component.

For the measurement by SP-ICP-MS, for example, it is possible to use Agilent 8800 triple quadrupole inductively coupled plasma mass spectrometry (ICP-MS, for semiconductor analysis, option #200) and Agilent 8900 manufactured by Agilent Technologies, Inc. and NexION 350S manufactured by PerkinElmer, Inc.

### (Coarse Particles)

The first treatment liquid may contain coarse particles, but it is preferable that a content thereof is preferably low.

The coarse particles mean particles having a diameter (particle diameter) of 0.1 um or more, in a case where a shape of the particles is regarded as a sphere.

The coarse particles contained in the first treatment liquid correspond to, for example, particles such as rubbish, dust, organic solid, and inorganic solid, which are contained as impurities in raw materials, and particles such as rubbish, dust, organic solid, and inorganic solid, which are brought in as contaminants during the preparation of the first treatment liquid, in which those particles are finally present as insoluble particles without being dissolved in the first treatment liquid.

It is more preferable that the first treatment liquid does not substantially include coarse particles. The fact that the coarse particles are not substantially included means that a content of particles having a particle diameter of 0.1 μm or more is 10,000 or less per 1 mL of the first treatment liquid, and it is preferably 5,000 or less. A lower limit thereof is preferably 0 or more, and more preferably 0.01 or more per milliliter of the first treatment liquid.

The content of the coarse particles present in the first treatment liquid can be measured in a liquid phase by using a commercially available measuring device in a light scattering type liquid particle measuring method using a laser as a light source.

Examples of a method for removing the coarse particles include a purification treatment such as filtering, which will be described later.

### <Manufacturing Method>

The method for manufacturing the first treatment liquid is not particularly limited, and known manufacturing methods can be used.

The first treatment liquid can be produced, for example, by mixing each component described above. Examples thereof include a method in which an oxidizing agent, an organic solvent, and, as necessary, other optional components are sequentially added to a container and then stirred and mixed. In a case where each component is added to the container, they may be added collectively or added dividedly a plurality of times.

As a stirring device and a stirring method used for preparing the first treatment liquid, a known device may be used as a stirrer or a disperser. Examples of a stirrer include an industrial mixer, a portable stirrer, a mechanical stirrer, and a magnetic stirrer. Examples of the disperser include an industrial disperser, a homogenizer, an ultrasonic disperser, and a beads mill.

The mixing of each component in the step of preparing the first treatment liquid, a purification treatment described later, and storage of the produced treatment liquid are preferably performed at 40° C. or lower, and more preferably performed at 30° C. or lower. The lower limit thereof is preferably 5° C. or higher and more preferably 10° C. or higher. By preparing, treating, and/or storing the first treatment liquid in the above-described temperature range, stable performance can be maintained for a long period of time.

It is preferable to perform a purification treatment on any one or more of raw materials for preparing the first treatment liquid or on the first treatment liquid after the preparation. Examples of the purification treatment include known methods such as distillation, ion exchange, and filtration (filtering).

Examples of a method of the purification treatment include a method of passing the raw material through an ion exchange resin, a reverse osmosis membrane (RO membrane), or the like, distillation of a raw material, and filtering.

The purification treatment may be performed by combining a plurality of the above-described purification methods. For example, the raw materials are subjected to primary purification by passing through an RO membrane, and then subjected to secondary purification by passing through a purification device consisting of a cation-exchange resin, an anion-exchange resin, or a mixed-bed type ion exchange resin.

In addition, the purification treatment may be performed a plurality of times.

It is preferable that handlings including production of the first treatment liquid, opening and cleaning of the container, and filling of the first treatment liquid, treatment analysis, and measurements are all performed in a clean room. It is preferable that the clean room meets the 14644-1 clean room standard. It is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

### Procedure of Step 1

The step 1 is a step of bringing an object to be treated into contact with the first treatment liquid.

The method for bringing the object to be treated into contact with the first treatment liquid is not particularly limited, and a known method can be used. Examples thereof include a method for immersing an object to be treated, in the first treatment liquid charged in a tank, a method for spraying the first treatment liquid onto an object to be treated, a method for allowing the first treatment liquid to flow onto an object to be treated, and any combination thereof.

Further, in order to further improve an oxidation ability of the first treatment liquid, a mechanical stirring method may be used.

Examples of the mechanical stirring method include a method for circulating the first treatment liquid on an object to be treated, a method for causing the first treatment liquid to flow on the object to be treated or spraying the first treatment liquid onto the object to be treated, and a method for stirring the first treatment liquid by using ultrasonic or megasonic waves.

A contact time between the object to be treated and the first treatment liquid can be appropriately adjusted, but is preferably 10 seconds to 20 minutes, more preferably 1 minute to 15 minutes, and even more preferably 3 minutes to 15 minutes.

A temperature of the first treatment liquid during the treatment is preferably 20° C. to 75° C. and more preferably 20° C. to 60° C.

By the above-described treatment, a part of the metal layer in a depth direction is oxidized, so that a metal oxide layer is formed. That is, by performing the above-described treatment, a laminate of the metal layer and the metal oxide layer is formed.

A material contained in the metal oxide layer depends on a material contained in the metal layer, but in a case where the metal layer contains molybdenum, the metal oxide layer contains a molybdenum oxide, in a case where the metal layer contains a molybdenum alloy, the metal oxide layer contains an oxide of a molybdenum alloy, in a case where the metal layer contains tungsten, the metal oxide layer contains a tungsten oxide, and in a case where the metal layer contains a tungsten alloy, the metal oxide layer contains an oxide of a tungsten alloy.

A thickness of the metal oxide layer formed by the step 1 is not particularly limited, but is preferably 0.1 to 30 nm and more preferably 0.2 to 10 nm.

### Step 2

The present treatment method includes the step 2 of bringing an object to be treated including the metal oxide layer formed in the step 1 into contact with a second treatment liquid to remove the metal oxide layer.

Hereinafter, the second treatment liquid used in the present step and the procedure thereof will be described.

### Second Treatment Liquid

The second treatment liquid contains water.

The second treatment liquid removes the metal oxide layer formed by the step 1, which is contained in the object to be treated, to expose the metal layer.

From the viewpoint of flatness, it is preferable that the second treatment liquid has a high resolution for the metal oxide layer and a low resolution for the metal layer.

### <Water>

The second treatment liquid contains water.

The water contained in the second treatment liquid may be any water as long as it does not adversely affect the object to be treated.

Among these, distilled water, DIW, and pure water (ultrapure water) are preferable, DIW or pure water is more preferable from the viewpoint of influence on a semiconductor and cost, and DIW is still more preferable.

The content of water is preferably 90% by mass or more, more preferably 95% by mass or more, still more preferably 99% by mass or more, and particularly preferably 100% by mass with respect to the total mass of the second treatment liquid.

### <Other Components>

The second treatment liquid may contain other components. Examples of the other components include an acidic compound, a basic compound, an organic solvent, an anticorrosion agent, and a surfactant.

### (Acidic Compound)

Examples of the acidic compound include the compounds described in the first treatment liquid, and hydrochloric acid, nitric acid, or sulfuric acid is preferable.

A content of the acidic compound is preferably 0.1% to 10.0% by mass, and more preferably 1.0% to 5.0% by mass with respect to the total mass of the treatment liquid.

### (Basic Compound)

Examples of the basic compound include the compounds mentioned in the first treatment liquid, and sodium hydroxide, potassium hydroxide, or ammonia is preferable.

A content of the basic compound is preferably 0.1% to 10.0% by mass, and more preferably 1.0% to 5.0% by mass with respect to the total mass of the treatment liquid.

### (Organic Solvent)

Examples of the organic solvent include the organic solvents mentioned in the first treatment liquid.

It is preferable that the organic solvent is mixed with water at an arbitrary ratio.

A content of the organic solvent is preferably 0.01% to 20.0% by mass, more preferably 0.1% to 10.0% by mass, and still more preferably 1.0% to 5.0% by mass with respect to the total mass of the second treatment liquid.

### (Anticorrosion Agent)

The anticorrosion agent is a compound that suppresses over-etching of the metal layer exposed in the step 2.

The anticorrosion agent is not particularly limited, and examples thereof include an azole compound, a pyrazine compound, a pyrimidine compound, an indole compound, an indolizine compound, an indazole compound, a quinoline compound, a pyrrole compound, and an oxazole compound, among which an azole compound is preferable.

The azole compound is an aromatic compound having a hetero-5-membered ring that contains at least one nitrogen atom.

Examples of the azole compound include an imidazole compound, a pyrazole compound, a thiazole compound, a triazole compound, and a tetrazole compound.

As the azole compound, the compounds described in paragraphs [0046] to [0050] of WO2021/166571A can be used by reference, the contents of which are incorporated in the present specification.

### (Surfactant)

The surfactant is not particularly limited as long as it is a compound having a hydrophilic group and a hydrophobic group (lipophilic group) in one molecule. Examples of the surfactant include an anionic surfactant, a cationic surfactant, and a nonionic surfactant.

Examples of the anionic surfactant include a phosphoric acid ester-based surfactant having a phosphoric acid ester group, a phosphonic acid-based surfactant having a phosphonate group, a sulfonic acid-based surfactant having a sulfo group, a carboxylic acid-based surfactant having a carboxy group, and a sulfuric acid ester-based surfactant having a sulfuric acid ester group.

As the anionic surfactant, for example, compounds described in paragraphs [0116] to [0123] of WO2022/044893A can be used, the contents of which are incorporated in the present specification.

Examples of the cationic surfactant include an alkylpyridium-based surfactant and an alkylamine acetate-based surfactant.

Examples of the nonionic surfactant include an ester-type nonionic surfactant, an ether-type nonionic surfactant, an ester-ether-type nonionic surfactant, and an alkanolamine-type nonionic surfactant, and an ether-type nonionic surfactant is preferable.

As the nonionic surfactant, for example, compounds described in paragraph [0126] of WO2022/044893A can be used, the contents of which are incorporated in the present specification.

### (Metal Component)

The second treatment liquid may contain a metal component.

Definition of the metal component, a suitable aspect of the content of the metal component in the second treatment liquid, and the measuring method are the same as those of the above-described first treatment liquid.

### (Coarse Particles)

The second treatment liquid may contain coarse particles, but it is preferable that a content thereof is preferably low.

Definition of the coarse particles, a suitable aspect of the content of the coarse particles in the second treatment liquid, and the measuring method are the same as those of the above-described first treatment liquid.

### Procedure of Step 2

The step 2 is a step of bringing an object to be treated, which has the metal oxide layer obtained in the step 1, into contact with the second treatment liquid.

The method for bringing the object to be treated into contact with the second treatment liquid is not particularly limited, and a known method can be used. For example, the contact method described in the step 1 can be used.

A contact time between the object to be treated and the second treatment liquid can be appropriately adjusted, but is preferably 10 seconds to 10 minutes and more preferably 20 seconds to 5 minutes.

A temperature of the second treatment liquid during the treatment is preferably 20° C. to 75° C. and more preferably 20° C. to 60° C.

In the present treatment method, it is preferable that the step 1 and the step 2 are repeatedly performed.

By repeatedly performing the step 1 and the step 2, a total amount of the etching amount of the metal layer removed by the present treatment method can be controlled with high accuracy.

In a case where the step 1 and the step 2 are alternately repeated, the number of times (the number of cycles) of the step 1 and the step 2 to be performed is preferably 2 or more, more preferably 3 or more, and from the viewpoint of excellent flatness, preferably 20 or less, more preferably 10 or less, and still more preferably 8 or less.

### Other Steps

The present treatment method may have other steps in addition to the above-described steps.

### First Rinsing Step

The present treatment method may have a first rinsing step of bringing the object to be treated obtained in the step 1 into contact with a first rinsing liquid to perform a rinsing treatment between the step 1 and the step 2.

By performing the present step, components of the first treatment liquid remaining on a surface of the object to be treated obtained in the step 1 can be removed.

The first rinsing liquid is not particularly limited as long as it does not adversely affect the object to be treated. However, an organic solvent is preferable.

As the organic solvent, the organic solvent used in the first treatment liquid can be suitably used.

The organic solvent used as the first rinsing liquid may be the same as or different from the organic solvent contained in the first treatment liquid, but is preferably mixed with the organic solvent contained in the first treatment liquid.

The organic solvent may be used alone, or two or more types thereof may be used in combination.

A method for bringing the first rinsing liquid into contact with the object to be treated is not particularly limited, and a known method can be used. For example, the method described in the method for bringing the first treatment liquid into contact with the object to be treated can be used.

A contact time between the first rinsing liquid and the object to be treated is not particularly limited, but is, for example, preferably 5 seconds to 10 minutes and more preferably 10 seconds to 5 minutes.

A temperature of the first rinsing liquid during the treatment is not particularly limited, but is preferably 15° C. to 75° C. and more preferably 20° C. to 55° C.

### Second Rinsing Step

The present treatment method may have a second rinsing step of performing a rinsing treatment by bringing the object to be treated obtained in the step 2 into contact with a second rinsing liquid, after the step 2.

Examples of the second rinsing liquid include water (preferably DIW), methanol, ethanol, IPA, N-methylpyrrolidinone, γ-butyrolactone, dimethyl sulfoxide, ethyl lactate, and propylene glycol monomethyl ether acetate, and DIW is preferable.

A method for bringing the second rinsing liquid into contact with the object to be treated is not particularly limited, and for example, the same method as the method mentioned in the first rinsing step can be used.

A contact time between the second rinsing liquid and the object to be treated is not particularly limited, but is, for example, preferably 5 seconds to 10 minutes and more preferably 10 seconds to 5 minutes.

A temperature of the second rinsing liquid during the treatment is not particularly limited, but is preferably 15° C. to 75° C. and more preferably 20° C. to 55° C.

### Drying Step

The present treatment method may have a drying step of performing a drying treatment as necessary.

A timing of performing the drying step is not particularly limited, but it is preferable to perform the drying step after the step 2 is performed.

In addition, in a case where the step 1 and the step 2 are performed a plurality of times, it is preferable that the drying step is performed at least after the step 2 is finally performed.

The method of the drying treatment is not particularly limited, and examples thereof include spin drying, placing the substrate under a drying gas stream, heating the substrate by a heating unit (for example, a hot plate and an infrared lamp), isopropyl alcohol (IPA) vapor drying, Marangoni drying, Rotagoni drying, and a combination of these.

A drying time may be appropriately adjusted according to the treatment liquid or the rinsing liquid used in the step, but is, for example, about 30 seconds to several minutes.

The present treatment method may have a step other than the above-described steps.

Examples of the steps other than the above-described steps include a coating film forming step described in paragraph [0021] of JP2019-061978A and a laser irradiation step described in paragraph [0022] of JP2019-061978A, the contents of which are incorporated in the present specification.

The present treatment method is preferably performed in a method for manufacturing an electronic device.

In addition, the present treatment method may be performed in combination with a step performed in the method for manufacturing an electronic device.

Examples of the step performed in the method for manufacturing an electronic device include a step of forming each structure such as a metal wire, a gate structure, a source structure, a drain structure, an insulating layer, a ferromagnetic layer, and/or a non-magnetic layer (layer formation, etching, a CMP and/or modification, or the like), a resist forming step, an exposure step and a removal step, a heat treatment step, a cleaning step, an examination step, and the like.

The present treatment method is preferably used for recess etching of metal layer wiring or a liner disposed on a substrate. As a result, a part of a metal wire can be removed to form a recess.

In addition, the present treatment method may be applied, for example, to NAND, dynamic random access memory (DRAM), static random access memory (SRAM), resistive random access memory (ReRAM), ferroelectric random access memory (FRAM (registered trademark)), magnetoresistive random access memory (MRAM), or phase change random access memory (PRAM), or applied to a logic circuit or a processor.

### EXAMPLES

Hereinafter, the present invention will be described in more detail based on Examples.

The materials, the amounts and proportions of the materials used, the details of treatments, the procedure of treatments, and the like shown in the following Examples can be appropriately modified as long as the gist of the present invention is maintained. Therefore, the scope of the present invention should not be construed as being limited to Examples shown below.

### Preparation of Treatment Liquid

The components shown below were mixed together in a predetermined formulation shown in the table below and sufficiently stirred, thereby preparing a treatment liquid and a rinsing liquid used in each step of each test. Unless otherwise specified, the content of the organic solvent and water in the treatment liquid is a remainder excluding components whose contents are specified, and in a case where the contents of the other components are not specified, the content is 100%.

Each raw material used in each treatment liquid shown below was of a high-purity grade, and was further distilled, ion-exchanged, filtered, or purified by a combination thereof in advance.

### <Solvent>

Butyl acetate (relative permittivity: 5.01, ester solvent)
Ethyl acetate (relative permittivity: 6.02, ester solvent)
Formic acid (relative permittivity: 58.5)
Dimethyl sulfoxide (relative permittivity: 48.9)
N-methyl-2-pyrrolidone (relative permittivity: 32.0)
1-propanol (relative permittivity: 22.2, alcohol solvent)
Isopropyl alcohol (relative permittivity: 18.3, alcohol solvent)
t-Butyl alcohol (relative permittivity: 11.4, alcohol solvent)
Ethyl lactate (relative permittivity: 13.1, ester solvent)
Pyridine (relative permittivity: 12.3, amine solvent)
Tetrahydrofuran (relative permittivity: 7.58, ether solvent)
Diethylene glycol diethyl ether (relative permittivity: 7.23, ether solvent)
Diethylene glycol dimethyl ether (relative permittivity: 5.97, ether solvent)
Propylene glycol monomethyl ether (relative permittivity: 12.3, ether solvent)
Propylene glycol monomethyl ether acetate (relative permittivity: 8.3, ester solvent)
Toluene (relative permittivity: 2.24)
Cyclohexane (relative permittivity: 2.05)
Hexane (relative permittivity: 1.89)
DIW: Deionized water (relative permittivity: 78.3)
1% by mass aqueous hydrochloric acid solution
1% by mass aqueous nitric acid solution
1% by mass aqueous ammonia solution
5% by mass aqueous hydrochloric acid solution
1% by mass NaOH aqueous solution

### <Oxidizing Agent>

1,4-Benzoquinone
Hydroquinone
1,2-Benzoquinone
1,4-naphthoquinone
Ubiquinone
Anthraquinone
Hydrogen peroxide

### Etching Treatment

As an object to be treated, a substrate was prepared in which a metal molybdenum (Mo) layer was formed on one surface of a 12-inch silicon wafer (diameter: 300 mm) by a CVD method. The thickness of the Mo layer was set to 30 nm.

### Examples A1 to A26

The first treatment liquid of each example adjusted to 25° C. was supplied to the obtained surface of the object to be treated for 10 minutes, thereby forming a metal oxide layer (step 1).

Next, a rinsing treatment was performed by supplying the first rinsing liquid of each example to the surface of the object to be treated at room temperature for 30 seconds (first rinsing step).

Next, the second treatment liquid of each example adjusted to 25° C. was supplied to the surface of the object to be treated for 1 minute to remove the metal oxide layer (step 2).

### Examples A27 to A29 and Comparative Example A2

The same treatment as in Examples A1 to A26 was performed except that various solutions (the first treatment liquid, the first rinsing liquid, and the second treatment liquid) shown in the table were used, the step 2 was further performed, and then the rinsing treatment was performed by supplying the second rinsing liquid of each example and comparative Example at room temperature to the surface of the object to be treated for 30 seconds (second rinsing step).

### Comparative Example A1

The same treatments as in Examples A1 to A26 were performed except that various solutions (the first treatment liquid and the second treatment liquid) shown in the table were used and the first rinsing step was not performed. The first treatment liquid used in Comparative Example A1 did not contain an oxidizing agent.

### Comparative Example A3

The same treatment as in Examples A1 to A26 was performed except that various solutions (the first treatment liquid and the first rinsing liquid) shown in the table were used and the step 2 was not performed.

### Examples B1 to B40 and B46 to B49

Using various solutions shown in the table, the same treatments (the step 1, the first rinsing step, and the step 2) as in Examples A1 to A26 were performed for 3 cycles.

### Examples B41 to B45 and Comparative Example B2

Using various solutions shown in the table, the same treatments (the step 1, the first rinsing step, the step 2, and the second rinsing step) as in Examples A27 to A29 and Comparative Example A2 were performed for 3 cycles.

### Comparative Example B1

The same treatment as in Comparative Example A1 was performed for 3 cycles.

### Comparative Example B3

The same treatment as in Comparative Example A3 was performed for 3 cycles.

### Examples C1 to C23

Each step was performed under conditions described in Table 4 below, using the treatment liquid and the rinsing liquid described in Example A27.

### Evaluation

### [Etching Amount]

A thickness of a molybdenum layer before and after the above-described etching treatment was measured using a thin film evaluation X-ray fluorescence spectrometer (XRF, manufactured by Rigaku Corporation, AZX-400), and the etching amount was calculated from a difference in thickness before and after the treatment.

The above-described etching amount is an etching amount per cycle.

In a case where the step 1 and the step 2 were performed for two or more cycles, the etching amount per cycle was calculated by dividing a total etching amount obtained from the difference between a thickness before the treatment and a thickness of the molybdenum layer after completion of all cycles by the number of cycles.

The obtained etching amount was evaluated according to the following evaluation standard.
A: 30 Å or more
B: 15 Å or more and less than 30 Å
C: 5 Å or more and less than 15 Å
D: less than 5 Å

### Flatness

The surface of the object to be treated after the treatment was measured using an atomic force microscope (AFM, manufactured by Hitachi High-Tech Corporation, NanoNavi Real), thereby calculating a surface roughness Ra.

In a case where the step 1 and the step 2 were performed for two or more cycles, a surface roughness after the completion of all the cycles was measured.

From the obtained value of the surface roughness Ra, the flatness was evaluated according to the following evaluation standard.
A: less than 0.5 nm
B: 0.5 nm or more and less than 0.7 nm
C: 0.7 nm or more and less than 1.0 nm
D: 1.0 nm or more and less than 1.2 nm
E: 1.2 nm or more

### Result

Tables 1 to 4 show compositions of each treatment liquid, conditions of the steps, and evaluation results.

TABLE 1

| | First treatment liquid | | | | | | | | | | |
|---|---|---|---|---|---|---|---|---|---|---|---|
| | Solvent | | | DIW | Oxidizing agent | | | | | | |
| | | Relative | Content | Content | | Content | First | Second | Second | Evaluation | |
| | | permit- | (% by | (% by | | (% by | rinsing | treatment | rinsing | Etching | Flat- |
| | Type | tivity | mass) | mass ) | Type | mass) | liquid | liquid | liquid | amount | ness |
| Example A1 | Butyl acetate | 5.01 | 98.5 | 0.5 | 1,4-benzoquinone | 1.0 | Butyl acetate | DIW | — | A | A |
| Example A2 | Ethyl acetate | 6.02 | 94.5 | 0.5 | Hydroquinone | 5.0 | Ethyl acetate | DIW | — | A | A |
| Example A3 | Ethyl acetate | 6.02 | 98.5 | 0.5 | 1,2-benzoquinone | 1.0 | Diethylene | DIW | — | A | A |
| | | | | | | | glycol | | | | |
| | | | | | | | diethyl ether | | | | |
| Example A4 | Butyl acetate | 5.01 | 98.5 | 0.5 | 1,4- | 1.0 | Butyl acetate | DIW | — | A | A |
| | | | | | naphthoquinone | | | | | | |
| Example A5 | Ethyl acetate | 6.02 | 94.5 | 0.5 | Ubiquinone | 5.0 | Ethyl acetate | DIW | — | B | A |
| Example A6 | Butyl acetate | 5.01 | 94.5 | 0.5 | Anthraquinone | 5.0 | Diethylene | DIW | — | B | A |
| | | | | | | | glycol | | | | |
| | | | | | | | diethyl ether | | | | |
| Example A7 | Butyl acetate | 5.01 | 99.4 | 0.1 | Hydrogen | 0.5 | Butyl acetate | DIW | — | A | D |
| | | | | | peroxide | | | | | | |
| Example A8 | 1-propanol | 22.2 | 98.5 | 0.5 | 1,4-benzoquinone | 1.0 | 1-propanol | DIW | — | A | D |
| Example A9 | Isopropyl | 18.3 | 98.5 | 0.5 | 1,4-benzoquinone | 1.0 | Isopropyl | DIW | — | A | C |
| | alcohol | | | | | | alcohol | | | | |
| Example | t-butyl | 11.4 | 98.5 | 0.5 | 1,4-benzoquinone | 1.0 | t-butyl alcohol | DIW | — | A | C |
| A10 | alcohol | | | | | | | | | | |
| Example | Ethyl lactate | 13.1 | 98.5 | 0.5 | 1,4-benzoquinone | 1.0 | Ethyl lactate | DIW | — | A | A |
| A11 | | | | | | | | | | | |
| Example | Diethylene | 7.23 | 98.5 | 0.5 | 1,4-benzoquinone | 1.0 | Diethylene | DIW | — | A | A |
| A12 | glycol | | | | | | glycol | | | | |
| | diethyl ether | | | | | | diethyl ether | | | | |
| Example | Ethyl acetate | 6.02 | 98.5 | 0.5 | 1,4-benzoquinone | 1.0 | Ethyl acetate | DIW | — | A | A |
| A13 | | | | | | | | | | | |
| Example | Butyl acetate | 5.01 | 98.5 | 0.5 | 1,4-benzoquinone | 1.0 | Butyl acetate | DIW | — | A | A |
| A14 | | | | | | | | | | | |
| Example | Diethylene | 5.97 | 98.5 | 0.5 | 1,4-benzoquinone | 1.0 | Diethylene | DIW | — | A | A |
| A15 | glycol | | | | | | glycol | | | | |
| | dimethyl | | | | | | diethyl ether | | | | |
| | ether | | | | | | | | | | |
| Example | Propylene | 8.30 | 98.5 | 0.5 | 1,4-benzoquinone | 1.0 | Propylene | DIW | — | A | A |
| A16 | glycol | | | | | | glycol | | | | |
| | monomethyl | | | | | | monomethyl | | | | |
| | ether acetate | | | | | | ether acetate | | | | |
| Example | Cyclohexane | 2.05 | 98.999 | 0.001 | 1,4-benzoquinone | 1.0 | Cyclohexane | DIW | — | B | C |
| A17 | | | | | | | | | | | |
| Example | Butyl acetate | 5.01 | 98.5 | 0.5 | 1,4-benzoquinone | 1.0 | Diethylene | DIW | — | A | A |
| A18 | | | | | | | glycol | | | | |
| | | | | | | | diethyl ether | | | | |
| Example | Ethyl acetate | 6.02 | 96.0 | 3.0 | 1,4-benzoquinone | 1.0 | Ethyl acetate | DIW | — | A | A |
| A19 | | | | | | | | | | | |
| Example | Propylene | 12.3 | 94.0 | 5.0 | 1,4-benzoquinone | 1.0 | Propylene | DIW | — | A | A |
| A20 | glycol | | | | | | glycol | | | | |
| | monomethyl | | | | | | monomethyl | | | | |
| | ether | | | | | | ether | | | | |
| Example | Propylene | 12.3 | 89.0 | 10.0 | 1,4-benzoquinone | 1.0 | Propylene | DIW | — | A | A |
| A21 | glycol | | | | | | glycol | | | | |
| | monomethyl | | | | | | monomethyl | | | | |
| | ether | | | | | | ether | | | | |
| Example | Propylene | 12.3 | 84.0 | 15.0 | 1,4-benzoquinone | 1.0 | Propylene | DIW | — | A | B |
| A22 | glycol | | | | | | glycol | | | | |
| | monomethyl | | | | | | monomethyl | | | | |
| | ether | | | | | | ether | | | | |
| Example | Butyl acetate | 5.01 | 94.5 | 0.5 | 1,4-benzoquinone | 5.0 | Butyl acetate | DIW | — | A | A |
| A23 | | | | | | | | | | | |
| Example | Butyl acetate | 5.01 | 98.5 | 0.5 | 1,4-benzoquinone | 1.0 | Isopropyl | DIW | — | A | A |
| A24 | | | | | | | alcohol | | | | |
| Example | Butyl acetate | 5.01 | 98.5 | 0.5 | 1,4-benzoquinone | 1.0 | Ethyl acetate | DIW | — | A | A |
| A25 | | | | | | | | | | | |
| Example | Butyl acetate | 5.01 | 98.5 | 0.5 | 1,4-benzoquinone | 1.0 | Cyclohexane | DIW | — | A | A |
| A26 | | | | | | | | | | | |
| Example | Butyl acetate | 5.01 | 98.5 | 0.5 | 1,4-benzoquinone | 1.0 | Butyl acetate | 1% by mass | DIW | A | A |
| A27 | | | | | | | | aqueous | | | |
| | | | | | | | | hydrochloric | | | |
| | | | | | | | | acid | | | |
| | | | | | | | | solution | | | |
| Example | Butyl acetate | 5.01 | 98.5 | 0.5 | 1,4-benzoquinone | 1.0 | Ethyl acetate | 1% by mass | DIW | A | A |
| A28 | | | | | | | | aqueous nitric | | | |
| | | | | | | | | acid | | | |
| | | | | | | | | solution | | | |
| Example | Butyl acetate | 5.01 | 98.5 | 0.5 | 1,4-benzoquinone | 1.0 | Butyl acetate | 1% by mass | DIW | A | A |
| A29 | | | | | | | | aqueous | | | |
| | | | | | | | | ammonia | | | |
| | | | | | | | | solution | | | |
| Comparative | Butyl acetate | 5.01 | 99.5 | 0.5 | — | — | — | DIW | — | D | C |
| Example A1 | | | | | | | | | | | |
| Comparative | DIW | 78.3 | 94.5 | 0.5 | Hydroquinone | 5.0 | DIW | 1% by mass | DIW | C | E |
| Example | | | | | | | | aqueous | | | |
| A2 | | | | | | | | hydrochloric | | | |
| | | | | | | | | acid | | | |
| | | | | | | | | solution | | | |
| Comparative | Butyl acetate | 5.01 | 98.5 | 0.5 | 1,4-benzoquinone | 1.0 | Butyl acetate | — | — | D | C |
| Example A3 | | | | | | | | | | | |

TABLE 2

| | First treatment liquid | | | | | | | | | | |
|---|---|---|---|---|---|---|---|---|---|---|---|
| | Solvent | | | DIW | Oxidizing agent | | | Second | | | |
| | | Relative | Content | Content | | Content | | treat- | Second | Evaluation | |
| | | permit- | (% by | (% by | | (% by | First rinsing | ment | rinsing | Etching | Flat- |
| | Type | tivity | mass) | mass) | Type | mass) | liquid | liquid | liquid | amount | ness |
| Example | Butyl acetate | 5.01 | 98.5 | 0.5 | 1,4-benzoquinone | 1.0 | Butyl acetate | DIW | — | A | A |
| B1 | | | | | | | | | | | |
| Example | Ethyl acetate | 6.02 | 94.5 | 0.5 | Hydroquinone | 5.0 | Ethyl acetate | DIW | — | A | A |
| B2 | | | | | | | | | | | |
| Example | Ethyl acetate | 6.02 | 98.5 | 0.5 | 1,2-benzoquinone | 1.0 | Ethyl acetate | DIW | — | A | A |
| B3 | | | | | | | | | | | |
| Example | Butyl acetate | 5.01 | 98.5 | 0.5 | 1,4- | 1.0 | Butyl acetate | DIW | — | A | A |
| B4 | | | | | naphthoquinone | | | | | | |
| Example | Ethyl acetate | 6.02 | 94.5 | 0.5 | Ubiquinone | 5.0 | Ethyl acetate | DIW | — | B | A |
| B5 | | | | | | | | | | | |
| Example | Butyl acetate | 5.01 | 94.5 | 0.5 | Anthraquinone | 5.0 | Butyl acetate | DIW | — | B | A |
| B6 | | | | | | | | | | | |
| Example | Butyl acetate | 5.01 | 99.4 | 0.1 | Hydrogen | 0.5 | Butyl acetate | DIW | — | A | D |
| B7 | | | | | peroxide | | | | | | |
| Example | Formic acid | 58.5 | 98.5 | 0.5 | 1,4-benzoquinone | 1.0 | Formic acid | DIW | — | A | D |
| B8 | | | | | | | | | | | |
| Example | Dimethyl | 48.9 | 98.5 | 0.5 | 1,4-benzoquinone | 1.0 | Dimethyl | DIW | — | A | D |
| B9 | sulfoxide | | | | | | sulfoxide | | | | |
| Example | N-methyl-2- | 32.0 | 98.5 | 0.5 | 1,4-benzoquinone | 1.0 | N-methyl-2- | DIW | — | A | D |
| B10 | pyrrolidone | | | | | | pyrrolidone | | | | |
| Example | 1-propanol | 22.2 | 98.5 | 0.5 | 1,4-benzoquinone | 1.0 | 1-propanol | DIW | — | A | D |
| B11 | | | | | | | | | | | |
| Example | Isopropyl | 18.3 | 98.5 | 0.5 | 1,4-benzoquinone | 1.0 | Isopropyl | DIW | — | A | C |
| B12 | alcohol | | | | | | alcohol | | | | |
| Example | t-butyl alcohol | 11.4 | 98.5 | 0.5 | 1,4-benzoquinone | 1.0 | t-butyl alcohol | DIW | — | A | C |
| B13 | | | | | | | | | | | |
| Example | Ethyl lactate | 13.1 | 98.5 | 0.5 | 1,4-benzoquinone | 1.0 | Ethyl lactate | DIW | — | A | A |
| B14 | | | | | | | | | | | |
| Example | Pyridine | 12.3 | 98.5 | 0.5 | 1,4-benzoquinone | 1.0 | Pyridine | DIW | — | A | B |
| B15 | | | | | | | | | | | |
| Example | Tetra- | 7.58 | 98.5 | 0.5 | 1,4-benzoquinone | 1.0 | Tetrahydrofuran | DIW | — | A | B |
| B16 | hydrofuran | | | | | | | | | | |
| Example | Diethylene | 7.23 | 98.5 | 0.5 | 1,4-benzoquinone | 1.0 | Diethylene | DIW | — | A | A |
| B17 | glycol | | | | | | glycol | | | | |
| | diethyl ether | | | | | | diethyl ether | | | | |
| Example | Butyl acetate | 6.02 | 98.5 | 0.5 | 1,4-benzoquinone | 1.0 | Ethyl acetate | DIW | — | A | A |
| B18 | | | | | | | | | | | |
| Example | Butyl acetate | 5.01 | 98.5 | 0.5 | 1,4-benzoquinone | 1.0 | Butyl acetate | DIW | — | A | A |
| B19 | | | | | | | | | | | |
| Example | Diethylene | 5.97 | 98.5 | 0.5 | 1,4-benzoquinone | 1.0 | Diethylene | DIW | — | A | A |
| B20 | glycol | | | | | | glycol | | | | |
| | dimethyl ether | | | | | | dimethyl ether | | | | |
| Example | Propylene | 12.3 | 98.5 | 0.5 | 1,4-benzoquinone | 1.0 | Propylene | DIW | — | A | A |
| B21 | glycol | | | | | | glycol | | | | |
| | monomethyl | | | | | | monomethyl | | | | |
| | ether | | | | | | ether | | | | |
| Example | Propylene | 8.3 | 98.5 | 0.5 | 1,4-benzoquinone | 1.0 | Propylene | DIW | — | A | A |
| B22 | glycol | | | | | | glycol | | | | |
| | monomethyl | | | | | | monomethyl | | | | |
| | ether acetate | | | | | | ether acetate | | | | |
| Example | Toluene | 2.24 | 98.95 | 0.05 | 1,4-benzoquinone | 1.0 | Toluene | DIW | — | B | C |
| B23 | | | | | | | | | | | |
| Example | Cyclohexane | 2.05 | 98.999 | 0.001 | 1,4-benzoquinone | 1.0 | Cyclohexane | DIW | — | B | C |
| B24 | | | | | | | | | | | |
| Example | Hexane | 1.89 | 98.999 | 0.001 | 1,4-benzoquinone | 1.0 | Hexane | DIW | — | B | C |
| B25 | | | | | | | | | | | |
| Example | Butyl acetate | 5.01 | 98.9999 | 0.0001 | 1,4-benzoquinone | 1.0 | Butyl acetate | DIW | — | C | A |
| B26 | | | | | | | | | | | |
| Example | Ethyl acetate | 6.02 | 98.999 | 0.001 | 1,4-benzoquinone | 1.0 | Ethyl acetate | DIW | — | B | A |
| B27 | | | | | | | | | | | |
| Example | Butyl acetate | 5.01 | 98.9 | 0.1 | 1,4-benzoquinone | 1.0 | Butyl acetate | DIW | — | A | A |
| B28 | | | | | | | | | | | |
| Example | Butyl acetate | 5.01 | 98.5 | 0.5 | 1,4-benzoquinone | 1.0 | Butyl acetate | DIW | — | A | A |
| B29 | | | | | | | | | | | |
| Example | Ethyl acetate | 6.02 | 96.0 | 3.0 | 1,4-benzoquinone | 1.0 | Ethyl acetate | DIW | — | A | A |
| B30 | | | | | | | | | | | |

TABLE 3

| | First treatment liquid | | | | | | | | | | |
|---|---|---|---|---|---|---|---|---|---|---|---|
| | Solvent | | | DIW | Oxidizing agent | | | | | | |
| | | Relative | Content | Content | | Content | | Second | Second | Evaluation | |
| | | permit- | (% by | (% by | | (% by | First rinsing | treatment | rinsing | Etching | Flat- |
| | Type | tivity | mass) | mass) | Type | mass | liquid | liquid | liquid | amount | ness |
| Example | Propylene | 12.3 | 94.0 | 5.0 | 1,4-benzoquinone | 1.0 | Propylene | DIW | — | A | A |
| B31 | glycol | | | | | | glycol | | | | |
| | monomethyl | | | | | | monomethyl | | | | |
| | ether | | | | | | ether | | | | |
| Example | Propylene | 12.3 | 89.0 | 10.0 | 1,4-benzoquinone | 1.0 | Propylene | DIW | — | A | A |
| B32 | glycol | | | | | | glycol | | | | |
| | monomethyl | | | | | | monomethyl | | | | |
| | ether | | | | | | ether | | | | |
| Example | Propylene | 12.3 | 84.0 | 15.0 | 1,4-benzoquinone | 1.0 | Propylene | DIW | — | A | B |
| B33 | glycol | | | | | | glycol | | | | |
| | monomethyl | | | | | | monomethyl | | | | |
| | ether | | | | | | ether | | | | |
| Example | Butyl acetate | 12.3 | 79.0 | 20.0 | 1,4-benzoquinone | 1.0 | Propylene | DIW | — | A | C |
| B34 | | | | | | | glycol | | | | |
| | | | | | | | monomethyl | | | | |
| | | | | | | | ether | | | | |
| Example | Butyl acetate | 5.01 | 97.5 | 0.5 | 1,4-benzoquinone | 2.0 | Butyl acetate | DIW | — | A | A |
| B35 | | | | | | | | | | | |
| Example | Butyl acetate | 5.01 | 94.5 | 0.5 | 1,4-benzoquinone | 5.0 | Butyl acetate | DIW | — | A | A |
| B36 | | | | | | | | | | | |
| Example | Butyl acetate | 5.01 | 89.5 | 0.5 | 1,4-benzoquinone | 10.0 | Butyl acetate | DIW | — | A | B |
| B37 | | | | | | | | | | | |
| Example | Butyl acetate | 5.01 | 98.5 | 0.5 | 1,4-benzoquinone | 1.0 | Isopropyl | DIW | — | A | A |
| B38 | | | | | | | alcohol | | | | |
| Example | Butyl acetate | 5.01 | 98.5 | 0.5 | 1,4-benzoquinone | 1.0 | Ethyl acetate | DIW | — | A | A |
| B39 | | | | | | | | | | | |
| Example | Butyl acetate | 5.01 | 98.5 | 0.5 | 1,4-benzoquinone | 1.0 | Cyclohexane | DIW | — | A | A |
| B40 | | | | | | | | | | | |
| Example | Butyl acetate | 5.01 | 98.5 | 0.5 | 1,4-benzoquinone | 1.0 | Butyl acetate | 1% by mass | DIW | A | A |
| B41 | | | | | | | | aqueous | | | |
| | | | | | | | | hydrochloric | | | |
| | | | | | | | | acid solution | | | |
| Example | Butyl acetate | 5.01 | 98.5 | 0.5 | 1,4-benzoquinone | 1.0 | Butyl acetate | 1% by mass | DIW | A | A |
| B42 | | | | | | | | aqueous | | | |
| | | | | | | | | nitric acid | | | |
| | | | | | | | | solution | | | |
| Example | Butyl acetate | 5.01 | 98.5 | 0.5 | 1,4-benzoquinone | 1.0 | Butyl acetate | 1% by mass | DIW | A | A |
| B43 | | | | | | | | aqueous | | | |
| | | | | | | | | ammonia | | | |
| | | | | | | | | solution | | | |
| Example | Butyl acetate | 5.01 | 98.5 | 0.5 | 1,4-benzoquinone | 1.0 | Butyl acetate | 5% by mass | DIW | A | A |
| B44 | | | | | | | | aqueous | | | |
| | | | | | | | | hydrochloric | | | |
| | | | | | | | | acid solution | | | |
| Example | Butyl acetate | 5.01 | 98.5 | 0.5 | 1,4-benzoquinone | 1.0 | Butyl acetate | 5% by mass | DIW | A | A |
| B45 | | | | | | | | NaOH | | | |
| | | | | | | | | aqueous | | | |
| | | | | | | | | solution | | | |
| Example | Butyl acetate | 5.01 | 98.5 | 0.5 | 1,4-benzoquinone | 0.9 | Butyl acetate | DIW | — | A | A |
| B46 | | | | | Hydroquinone | 0.1 | | | | | |
| Example | Butyl acetate | 5.01 | 98.5 | 0.5 | 1,4-benzoquinone | 0.8 | Butyl acetate | DIW | — | A | A |
| B47 | | | | | 1,4-naphthoquinone | 0.2 | | | | | |
| Example | Butyl acetate | 5.01 | 90.0 | 0.5 | 1,4-benzoquinone | 1.0 | Butyl acetate | DIW | — | A | A |
| B48 | Ethyl acetate | 6.02 | 8.5 | | | | | | | | |
| Example | Ethyl acetate | 6.02 | 50.0 | 0.5 | 1,4-benzoquinone | 1.0 | Butyl acetate | DIW | — | A | A |
| B49 | Diethylene | 12.3 | 48.5 | | | | | | | | |
| | glycol | | | | | | | | | | |
| | diethyl ether | | | | | | | | | | |
| Comparative | Butyl acetate | 5.01 | 99.5 | 0.5 | — | — | — | DIW | — | D | C |
| Example B1 | | | | | | | | | | | |
| Comparative | DIW | 78.3 | 94.5 | 0.5 | Hydroquinone | 5.0 | DIW | 1% by mass | DIW | C | E |
| Example | | | | | | | | aqueous | | | |
| B2 | | | | | | | | hydrochloric | | | |
| | | | | | | | | acid solution | | | |
| Comparative | Butyl acetate | 5.01 | 98.5 | 0.5 | 1,4-benzoquinone | 1.0 | Butyl acetate | — | — | D | C |
| Example B3 | | | | | | | | | | | |

TABLE 4

| | Step 1 | | First rinsing step | | Step 2 | | Second rinsing step | | | | |
|---|---|---|---|---|---|---|---|---|---|---|---|
| | Treatment | Temper- | Treatment | Temper- | Treatment | Temper- | Treatment | Temper- | Number | Evaluation | |
| | time | ature | time | ature | time | ature | time | ature | of cycles | Etching | |
| | (minutes) | (° C.) | (minutes) | (° C.) | (minutes) | (° C.) | (minutes) | (° C.) | (times) | amount | Flatness |
| Example | 10.0 | 25 | 0.5 | 25 | 1.0 | 25 | 0.5 | 25 | 3 | A | A |
| C1 | | | | | | | | | | | |
| Example | 5.0 | 25 | 0.5 | 25 | 1.0 | 25 | 0.5 | 25 | 3 | A | A |
| C2 | | | | | | | | | | | |
| Example | 1.0 | 25 | 0.5 | 25 | 1.0 | 25 | 0.5 | 25 | 3 | B | A |
| C3 | | | | | | | | | | | |
| Example | 5.0 | 25 | 0.5 | 25 | 2.0 | 25 | 0.5 | 25 | 3 | A | A |
| C4 | | | | | | | | | | | |
| Example | 5.0 | 25 | 0.5 | 25 | 5.0 | 25 | 0.5 | 25 | 3 | A | A |
| C5 | | | | | | | | | | | |
| Example | 5.0 | 25 | 0.5 | 25 | 0.5 | 25 | 0.5 | 25 | 3 | A | A |
| C6 | | | | | | | | | | | |
| Example | 5.0 | 25 | — | — | 1.0 | 25 | 0.5 | 25 | 3 | A | A |
| C7 | | | | | | | | | | | |
| Example | 5.0 | 25 | 1.0 | 25 | 1.0 | 25 | 0.5 | 25 | 3 | A | A |
| C8 | | | | | | | | | | | |
| Example | 5.0 | 25 | 5.0 | 25 | 1.0 | 25 | 0.5 | 25 | 3 | A | A |
| C9 | | | | | | | | | | | |
| Example | 5.0 | 25 | 0.5 | 25 | 1.0 | 25 | 1.0 | 25 | 3 | A | A |
| C10 | | | | | | | | | | | |
| Example | 5.0 | 25 | 0.5 | 25 | 1.0 | 25 | 5.0 | 25 | 3 | A | A |
| C11 | | | | | | | | | | | |
| Example | 1.0 | 50 | 0.5 | 25 | 1.0 | 25 | 0.5 | 25 | 3 | A | A |
| C12 | | | | | | | | | | | |
| Example | 5.0 | 50 | 0.5 | 25 | 1.0 | 25 | 0.5 | 25 | 3 | A | A |
| C13 | | | | | | | | | | | |
| Example | 5.0 | 25 | 5.0 | 25 | 1.0 | 5C | 0.5 | 25 | 3 | A | A |
| C14 | | | | | | | | | | | |
| Example | 1.0 | 50 | 0.5 | 25 | 1.0 | 50 | 0.5 | 25 | 3 | A | A |
| C15 | | | | | | | | | | | |
| Example | 5.0 | 25 | 0.5 | 50 | 1.0 | 25 | 0.5 | 25 | 3 | A | A |
| C16 | | | | | | | | | | | |
| Example | 5.0 | 25 | 0.5 | 50 | 1.0 | 25 | 0.5 | 50 | 3 | A | A |
| C17 | | | | | | | | | | | |
| Example | 5.0 | 25 | 0.5 | 25 | 1.0 | 25 | 0.5 | 25 | 1 | A | A |
| C18 | | | | | | | | | | | |
| Example | 5.0 | 25 | 0.5 | 25 | 1.0 | 25 | 0.5 | 25 | 5 | A | A |
| C19 | | | | | | | | | | | |
| Example | 5.0 | 25 | 0.5 | 25 | 1.0 | 25 | 0.5 | 25 | 7 | A | A |
| C20 | | | | | | | | | | | |
| Example | 5.0 | 25 | 0.5 | 25 | 1.0 | 25 | 0.5 | 25 | 10 | A | B |
| C21 | | | | | | | | | | | |
| Example | 1.0 | 25 | 0.5 | 25 | 1.0 | 25 | 0.5 | 25 | 5 | B | A |
| C22 | | | | | | | | | | | |
| Example | 1.0 | 50 | 0.5 | 25 | 1.0 | 25 | 0.5 | 25 | 5 | A | A |
| C23 | | | | | | | | | | | |

From the results shown in the above-described table, it was confirmed that the treatment method according to the embodiment of the present invention is excellent in the etching amount and the flatness of the surface of the object to be treated after the treatment.

From a comparison of Examples A1 to A7 and Examples B1 to B7, it was confirmed that in a case where the oxidizing agent was a quinone compound or hydroquinone, the flatness was more excellent, and in a case where the oxidizing agent was 1,4-benzoquinone, hydroquinone, 1,2-benzoquinone, or 1,4-naphthoquinone, the etching amount was further excellent.

From a comparison of Examples A8 to A17 and Examples B8 to B25, it was confirmed that in a case where the relative permittivity of the organic solvent was 50 or less, the flatness was more excellent, and in a case where the relative permittivity of the organic solvent was 3.0 to 20.0, the effect of the present invention was further excellent.

In addition, from the comparison of Examples A8 to A17 and Examples B8 to B25, it was confirmed that in a case where the organic solvent is an ether solvent, an ester solvent, or an amine solvent, the effect of the present invention is more excellent, and in a case where the organic solvent is an ester solvent or a glycol ether, the effect of the present invention is further excellent.

From a comparison of Examples A19 to A22 and Examples B26 to B34, it was confirmed that in a case where the content of water in the first treatment liquid is 0.001% to 15.0% by mass with respect to the total mass of the first treatment liquid, the effect of the present invention is more excellent, and in a case where the content of water in the first treatment liquid is 0.1% to 10.0% by mass with respect to the total mass of the first treatment liquid, the effect of the present invention is further excellent.

From a comparison of Examples A1 and A23 and Examples B1 and B35 to B37, it was confirmed that in a case where the content of the oxidizing agent in the first treatment liquid was 7.5% by mass or less with respect to the total mass of the first treatment liquid, the flatness was more excellent.

From a comparison of Examples C1 to C3, it was confirmed that in a case where a treatment time of the step 1 was 3 minutes or more, the etching amount was more excellent.

From a comparison of Examples C18 to C21, it was confirmed that the flatness was more excellent in a case where the number of cycles was 1 to 8.

As a result of performing the same treatments and evaluations as in Example A15 except that tetraethylene glycol dimethyl ether was used as the organic solvent and the first rinsing liquid in the first treatment liquid, the same results as in Example A15 were obtained.

Further, in a case where the same treatments and evaluations as in Example B20 were performed except that tetraethylene glycol dimethyl ether, diethylene glycol dibutyl ether, or dipropylene glycol dimethyl ether was used as the organic solvent and the first rinsing liquid in the first treatment liquid, the same results as in Example B20 were obtained.

What is claimed is:

1. A method for treating an object to be treated, comprising:
a step 1 of bringing the object to be treated, which has a metal layer containing at least one selected from the group consisting of molybdenum and tungsten, into contact with a first treatment liquid to form a metal oxide layer; and
a step 2 of bringing the object to be treated, which has the metal oxide layer, into contact with a second treatment liquid to remove the metal oxide layer,
wherein the first treatment liquid contains an organic solvent and an oxidizing agent, and
the second treatment liquid contains water.

2. The method for treating an object to be treated according to claim 1,
wherein a content of the organic solvent is 80% by mass or more with respect to a total mass of the first treatment liquid.

3. The method for treating an object to be treated according to claim 1,
wherein a relative permittivity of the organic solvent is 50 or less.

4. The method for treating an object to be treated according to claim 1,
wherein a relative permittivity of the organic solvent is 3 to 20.

5. The method for treating an object to be treated according to claim 1,
wherein the organic solvent includes at least one selected from the group consisting of an ester solvent, an ether solvent, and an amine solvent.

6. The method for treating an object to be treated according to claim 1,
wherein the organic solvent includes at least one selected from the group consisting of ethyl acetate, butyl acetate, ethyl lactate, tetraethylene glycol dimethyl ether, diethylene glycol dibutyl ether, diethylene glycol dimethyl ether, dipropylene glycol dimethyl ether, propylene glycol monomethyl ether, propylene glycol monomethyl ether acetate, diethylene glycol diethyl ether, tetrahydrofuran, and pyridine.

7. The method for treating an object to be treated according to claim 1,
wherein the first treatment liquid contains water, and a content of the water is 0.001% to 20.0% by mass with respect to a total mass of the first treatment liquid.

8. The method for treating an object to be treated according to claim 7,
wherein the content of the water is 0.1% to 10.0% by mass with respect to the total mass of the first treatment liquid.

9. The method for treating an object to be treated according to claim 1,
wherein the oxidizing agent includes at least one selected from the group consisting of a quinone compound and a hydroquinone.

10. The method for treating an object to be treated according to claim 1,
wherein the oxidizing agent includes at least one selected from the group consisting of 1,2-benzoquinone, 1,4-benzoquinone, hydroquinone, 1,4-naphthoquinone, ubiquinone, and anthraquinone.

11. The method for treating an object to be treated according to claim 1,
wherein the step 1 and the step 2 are repeatedly performed.

12. A treatment liquid applied to an object to be treated, which has a metal layer containing at least one selected from the group consisting of molybdenum and tungsten, the treatment liquid comprising:
an organic solvent; and
an oxidizing agent,
wherein a content of the organic solvent is 80% by mass or more with respect to a total mass of the treatment liquid.

13. A method for manufacturing an electronic device, comprising:
the method for treating an object to be treated according to claim 1.

14. The method for treating an object to be treated according to claim 2,
wherein a relative permittivity of the organic solvent is 50 or less.

15. The method for treating an object to be treated according to claim 2,
wherein a relative permittivity of the organic solvent is 3 to 20.

16. The method for treating an object to be treated according to claim 2,
wherein the organic solvent includes at least one selected from the group consisting of an ester solvent, an ether solvent, and an amine solvent.

17. The method for treating an object to be treated according to claim 2,
wherein the organic solvent includes at least one selected from the group consisting of ethyl acetate, butyl acetate, ethyl lactate, tetraethylene glycol dimethyl ether, diethylene glycol dibutyl ether, diethylene glycol dimethyl ether, dipropylene glycol dimethyl ether, propylene glycol monomethyl ether, propylene glycol monomethyl ether acetate, diethylene glycol diethyl ether, tetrahydrofuran, and pyridine.

18. The method for treating an object to be treated according to claim 2,
wherein the first treatment liquid contains water, and a content of the water is 0.001% to 20.0% by mass with respect to a total mass of the first treatment liquid.

19. The method for treating an object to be treated according to claim 18,
wherein the content of the water is 0.1% to 10.0% by mass with respect to the total mass of the first treatment liquid.

20. The method for treating an object to be treated according to claim 2,
wherein the oxidizing agent includes at least one selected from the group consisting of a quinone compound and a hydroquinone.
